(19) United States
(12) Patent Application Publication
(10) Pub. No.: US 2025/0293129 A1
(43) Pub. Date: Sep. 18, 2025

(54) SUBSTRATE UNIT

(71) Applicant: Kioxia Corporation, Tokyo (JP)

(72) Inventor: Katsuya MURAKAMI, Tokyo (JP)

(21) Appl. No.: 19/061,125

(22) Filed: Feb. 24, 2025

(30) Foreign Application Priority Data
Mar. 15, 2024 (JP) 2024-041750

(51) Int. Cl. H01L 23/498

(52) U.S. Cl. CPC H01L 23/49811; H01L 23/49894

(57) ABSTRACT

A substrate unit includes an insulating substrate; a first pad provided on the insulating substrate; a second pad provided on the insulating substrate; a solder resist layer including a portion provided on the insulating substrate and an opening configured to expose the first pad and the second pad; a first insulating portion provided between the first pad and the second pad in the opening; and an electronic part having a first terminal connected to the first pad and a second terminal connected to the second pad. The solder resist layer includes a first insulating material. The first insulating portion includes a second insulating material. A length in a direction of the first insulating portion is greater than a length in the direction of the first pad, the direction extending from the first pad toward the insulating substrate.

### CROSS-REFERENCE TO RELATED APPLICATION(S)

This application is based upon and claims the benefit of priority from Japanese Patent Application No. 2024-041750, filed Mar. 15, 2024, the entire contents of which are incorporated herein by reference.

### FIELD

Embodiments described herein relate generally to a substrate unit.

### BACKGROUND

In general, a substrate unit has a pad provided on an insulating base material (an insulating substrate, an insulating base body), a solder resist layer having an opening that causes the pad to be exposed, and an electronic part connected to the pad.

### DESCRIPTION OF THE DRAWINGS

FIG. 1 is a perspective view showing a semiconductor storage device of a first embodiment.

FIG. 2 is a sectional view showing one portion of a substrate of the first embodiment.

FIG. 3 is a sectional view along an F3-F3 line of the substrate shown in FIG. 2.

FIG. 4 is a sectional view showing one portion of a substrate unit of the first embodiment.

FIG. 5 is a sectional view showing a method of manufacturing the substrate unit of the first embodiment.

FIG. 6 is a sectional view showing a method of manufacturing the substrate unit of the first embodiment.

FIG. 7 is a sectional view showing one portion of a substrate of a second embodiment.

FIG. 8 is a sectional view showing one portion of a substrate of a third embodiment.

FIG. 9 is a sectional view along an F9-F9 line of the substrate shown in FIG. 8.

FIG. 10 is a sectional view showing one portion of a substrate unit of a fourth embodiment.

FIG. 11 is a sectional view along an F11-F11 line of the substrate shown in FIG. 10.

### DETAILED DESCRIPTION

Embodiments provide a substrate unit such that a restriction of occurrences of manufacturing failures can be achieved.

In general, according to one embodiment, a substrate unit include an insulating substrate; a first pad provided on the insulating substrate; a second pad provided on the insulating substrate; a solder resist layer including a portion provided on the insulating substrate and an opening configured to expose the first pad and the second pad; a first insulating portion provided between the first pad and the second pad in the opening; and an electronic part having a first terminal connected to the first pad across a joining material and a second terminal connected to the second pad across a joining material. The solder resist layer includes a first insulating material. The first insulating portion includes a second insulating material different from the first insulating material. When a direction extending from the first pad toward the insulating substrate is a first direction, a length in the first direction of the first insulating portion is greater than a length in the first direction of the first pad.

Hereafter, a substrate unit of embodiments will be described, with reference to the drawings. In the following description, identical reference signs will be allotted to configurations having identical or similar functions. Further, redundant descriptions of these configurations may be omitted. In the present application, “parallel”, “perpendicular”, and “the same” may include cases of being “approximately “parallel”, “approximately perpendicular”, and “approximately the same” respectively. In the present application, “connection”, not being limited to a mechanical connection, may include an electrical connection. That is, “connection”, not being limited to a case of being connected directly to an object, may include a case of being connected to an object with another element interposed. In the present application, “coincide” means that virtual projected images of two objects coincide. That is, “coincide”, not being limited to a case in which two objects are in contact, may include a case in which two objects are not in contact (for example, a case in which a space or another element exists between the two objects).

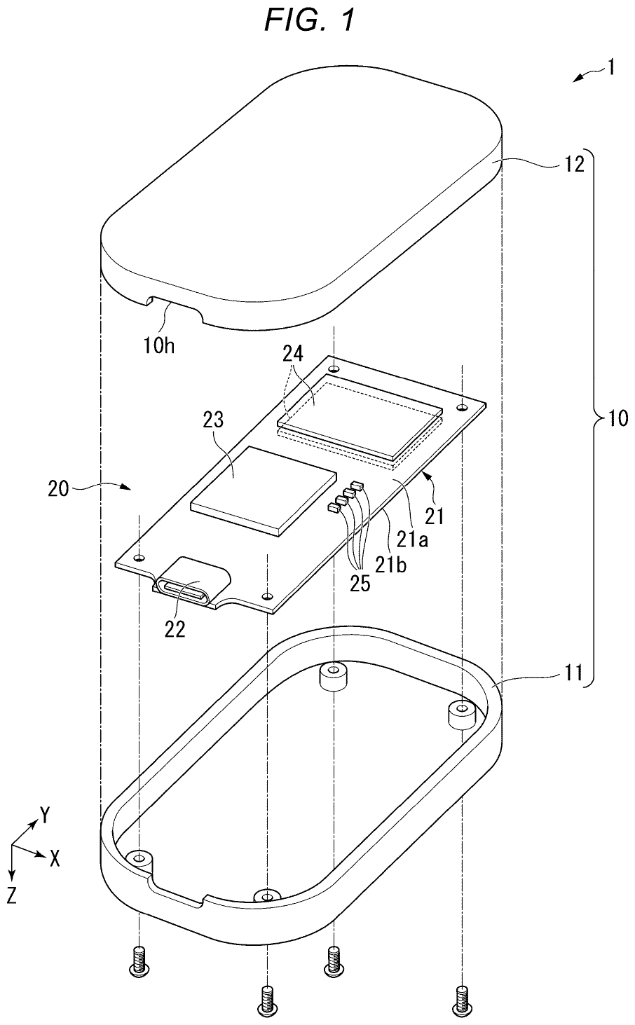

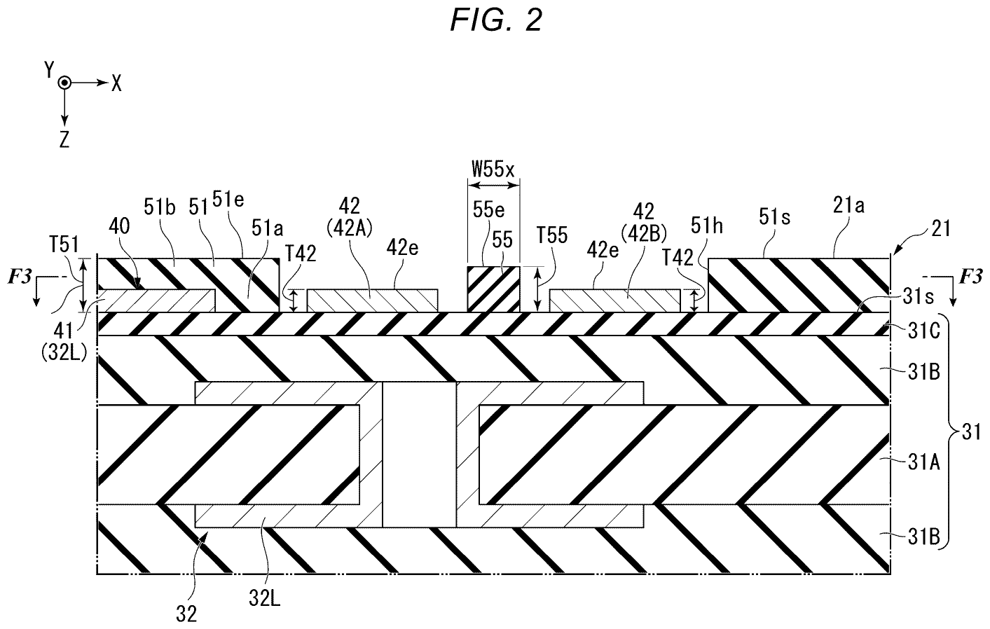

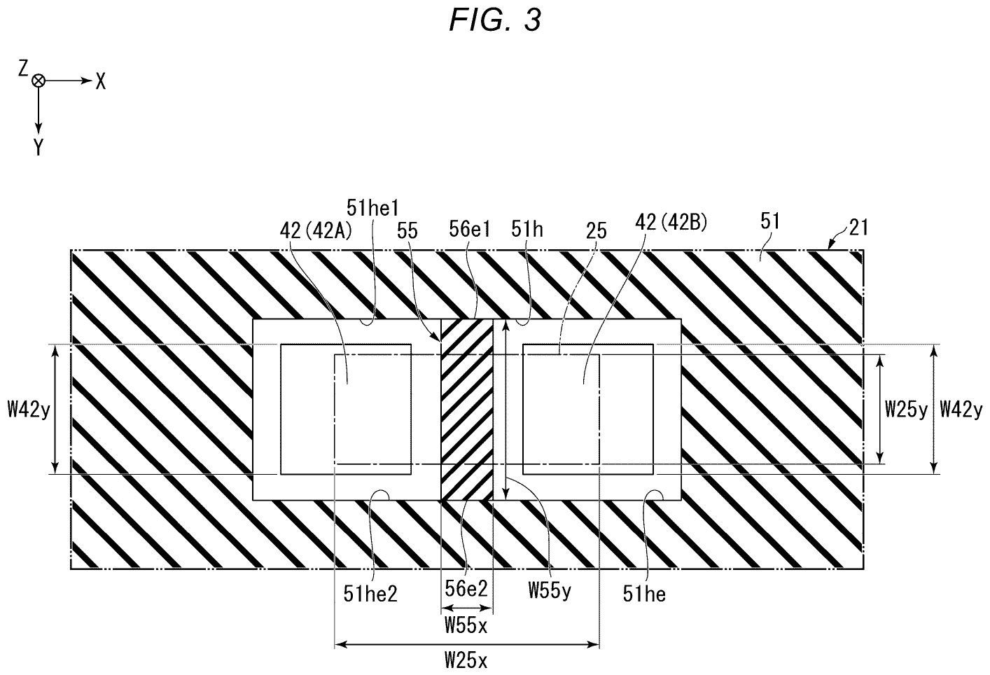

In the present application, an X direction, a Y direction, and a Z direction are defined as follows. The X direction and the Y direction are directions parallel to a first face 21a of a substrate 21 to be described hereafter (refer to FIG. 1). The X direction is a direction heading from a first pad 42A, to be described hereafter, toward a second pad 42B (refer to FIG. 3). The Y direction is a direction that intersects (for example, is perpendicular to) the X direction (refer to FIG. 3). The Z direction is a direction that intersects (for example, is perpendicular to) the X direction and the Y direction. The Z direction is a direction heading from the first pad 42A, to be described hereafter, toward an insulating base material 31 (refer to FIG. 2). The Z direction is one example of a “first direction”. The X direction is one example of a “second direction”. The Y direction is one example of a “third direction”.

### First Embodiment

### 1. Semiconductor Storage Device Overall Configuration

A semiconductor storage device 1 including a substrate unit 20 of a first embodiment will be described, with reference to FIGS. 1 to 6. The semiconductor storage device 1 is a storage device such as a solid-state drive (SSD). The semiconductor storage device 1 is connected to a host apparatus, and is used as a storage device of the host apparatus. The host apparatus is a server, a personal computer, a mobile apparatus, a video recorder, or a vehicle-mounted apparatus, but is not limited to these examples.

The semiconductor storage device 1 is one example of a “semiconductor device”. The substrate unit 20 is also applicable to a semiconductor device differing from a semiconductor storage device. A semiconductor device differing from a semiconductor storage device may be, for example, a device including a semiconductor part (for example, a semiconductor integrated circuit), such as a central processing unit (CPU), a graphics processing unit (GPU), an application-specific integrated circuit (ASIC), a programmable logic device (PLD), or a field-programmable gate array (FPGA), or may be a device including another kind of semiconductor part, such as a diode, a transistor, or an amplifier. Although these semiconductor devices are, for example, a server, a personal computer, a mobile apparatus, a video recorder, or a vehicle-mounted apparatus, the semiconductor devices are not limited to these examples.

FIG. 1 is a perspective view showing the semiconductor storage device 1. The semiconductor storage device 1 has, for example, a housing 10 and the substrate unit 20.

### 1.1 Housing

The housing 10 is a member that forms an outer shell of the semiconductor storage device 1. The housing 10 houses the substrate unit 20. The housing 10 includes, for example, a base 11 and a cover 12. The cover 12 faces the substrate unit 20 from a side opposite to that of the base 11. The housing 10 is formed by, for example, the base 11 and the cover 12 being combined. The semiconductor storage device 1 need not have the housing 10. In this case, the substrate unit 20 alone may correspond to one example of a “semiconductor device”.

### 1.2 Substrate Unit

Next, the substrate unit 20 will be described. The substrate unit 20 is an assembly including a substrate and a semiconductor part. The substrate unit 20 has, for example, the substrate 21, a connector 22, a controller 23, a multiple of NAND flash memories 24 (hereafter called the “NAND 24”), and a multiple of electronic parts 25.

The substrate 21 is a plate member that follows the X direction and the Y direction. The substrate 21 is a printed substrate, and includes the insulating base material 31, and a wiring pattern 32 provided on the insulating base material 31 (refer to FIG. 2). The substrate 21 has the first face 21a, and a second face 21b positioned on a side opposite to that of the first face 21a. Each of the first face 21a and the second face 21b extends in the X direction and the Y direction.

The connector 22 is a connection portion that can be connected to a connector of a host instrument. The connector 22 includes a multiple of metal terminals that can be connected to a connector of a host instrument. The connector 22 is provided in, for example, an end portion of the substrate 21. The connector 22 is exposed in an outer portion of the housing 10 through an opening 10h of the housing 10.

The controller 23 is a part that comprehensively controls a whole of the semiconductor storage device 1. The controller 23 is, for example, a semiconductor package including a system on a chip (SoC) such that a host interface circuit with respect to a host instrument, a control circuit that controls the multiple of NANDs 24, and the like are integrated on one semiconductor chip. The controller 23 is provided on, for example, the first face 21a of the substrate 21. The controller 23 is one example of a “semiconductor part”.

The NAND 24 is a semiconductor package including a non-volatile semiconductor memory chip. The NAND 24 is provided on, for example, the first face 21a and the second face 21b of the substrate 21. The NAND 24 is one example of a “semiconductor memory”, and is one example of a “semiconductor part”. A “semiconductor memory” or a “semiconductor part” in the present application, not being limited to the NAND 24, may be another kind of semiconductor memory, such as a NOR memory, a magnetoresistive random-access memory (MRAM), or a resistive random-access memory.

The multiple of electronic parts 25 are provided on the first face 21a and the second face 21b of the substrate 21. The electronic part 25 includes, for example, the electronic part 25 that is a miniature part whose longitudinal length is 1 mm or less. Hereafter, a mounting structure of the electronic part 25 will be described.

### 2. Electronic Part Mounting Structure

### 2.1 Substrate Configuration

Firstly, a configuration of the substrate 21 will be described.

FIG. 2 is a sectional view showing one portion of the substrate 21. The substrate 21 is, for example, a multilayer circuit substrate. The substrate 21 includes the insulating base material 31 and the wiring pattern 32.

The insulating base material 31 is an insulating member that forms a base portion of the substrate 21. The insulating base material 31 is formed of, for example, a hard insulating material such as a glass epoxy material. A material that is the insulating base material 31 is not limited to the aforementioned example. The insulating base material 31 may also be formed of a paper phenolic material, a composite material, a fluorine-based range material, a polyimide material, or the like.

In the present embodiment, the insulating base material 31 includes a core member 31A, a bonding sheet 31B, and a prepreg 31C. The bonding sheet 31B is superimposed on the core member 31A. The prepreg 31C is integrated with the core member 31A across the bonding sheet 31B. The prepreg 31C is positioned on a surface layer side of the substrate 21 with respect to the core member 31A. The substrate 21, not being limited to a multilayer circuit substrate, may be a double-sided substrate. That is, the insulating base material 31 may be formed of only the core member 31A, without having the bonding sheet 31B or the prepreg 31C.

The insulating base material 31 has a surface 31s on which wiring 41 and a pad 42, to be described hereafter, are provided. The surface 31s extends in the X direction and the Y direction. The surface 31s is one example of a “first face”.

The wiring pattern 32 is a conductive portion provided on the substrate 21. The wiring pattern 32 includes wiring 32L provided in an interior of the insulating base material 31 and/or on a surface of the insulating base material 31. The wiring pattern 32 is formed of, for example, a metal material such as copper.

### 2.2 Substrate Surface Layer Portion Configuration

Next, a surface layer portion of the substrate 21 will be described. The surface layer portion of the substrate 21 has, for example, a conductive pattern 40, a solder resist layer 51, and an insulating portion 55.

### 2.2.1 Conductive Pattern

Firstly, the conductive pattern 40 will be described. The conductive pattern 40 is a conductive portion provided in the surface layer portion as one portion of the wiring pattern 32. The conductive pattern 40 has the wiring 41 and a multiple of the pad 42.

### Wiring

The wiring 41 is wiring provided in the surface layer portion as one portion of the wiring 32L. The wiring 41 is provided on the surface 31s of the insulating base material 31.

### Pad

The multiple of pads 42 are provided on the surface 31s of the insulating base material 31. The multiple of pads 42 include, for example, the first pad 42A and the second pad 42B. The first pad 42A and the second pad 42B are disposed separated in, for example, the X direction. Each of the first pad 42A and the second pad 42B is of, for example, a rectangular form when seen from the Z direction (refer to FIG. 3). Each of the first pad 42A and the second pad 42B may be of a circular form, or may have another form. Hereafter, the first pad 42A and the second pad 42B will be called simply “the pad 42” when not distinguishing between the two.

The pad 42 has a thickness (for example, a maximum thickness) T42 as a Z direction thickness (Z direction length). The pad 42 has an end 42e positioned on a side opposite to that of the insulating base material 31 when seen in a cross-section following the Z direction (a cross-section shown in FIG. 2). The thickness T42 of the pad 42 corresponds to a height of the end 42e of the pad 42 with respect to the surface 31s of the insulating base material 31. The end 42e is one example of a “first end”.

### 2.2.2 Solder Resist Layer

Next, the solder resist layer 51 will be described. The solder resist layer 51 is an insulating protective layer that protects the conductive pattern 40. The solder resist layer 51 has a surface 51s positioned on a side opposite to that of the insulating base material 31. The surface 51s of the solder resist layer 51 forms the first face 21a of the substrate 21.

The solder resist layer 51 includes a first portion 51a and a second portion 51b. The first portion 51a is provided on the surface 31s of the insulating base material 31, and is in contact with the insulating base material 31. The second portion 51b covers the conductive pattern 40 from the Z direction. For example, the second portion 51b covers the wiring 41.

The solder resist layer 51 has an opening 51h that causes the first pad 42A and the second pad 42B to be exposed collectively. The opening 51h is, for example, rectangular when seen from the Z direction (refer to FIG. 3).

The solder resist layer 51 has a thickness (for example, a maximum thickness) T51 as a Z direction thickness. The thickness T51 is a Z direction thickness (for example, a maximum thickness) of the first portion 51a of the solder resist layer 51. The solder resist layer 51 has an end 51e positioned on a side opposite to that of the insulating base material 31 when seen in a cross-section following the Z direction (a cross-section shown in FIG. 2). The Z direction thickness T51 of the solder resist layer 51 corresponds to a height of the end 51e of the solder resist layer 51 with respect to the surface 31s of the insulating base material 31. The Z direction thickness T51 of the solder resist layer 51 is large in comparison with the Z direction thickness T42 of the pad 42.

The solder resist layer 51 includes a first insulating material. The first insulating material is an insulating material that forms a general solder resist layer. The first insulating material is, for example, an epoxy resin. The solder resist layer 51 is formed by, for example, applying the first insulating material onto the insulating base material 31 using a curtain coater, screen printing, a spray coater, or the like, and curing the applied first insulating material by heating, exposing to ultraviolet light, or the like.

Next, the insulating portion 55 will be described. The insulating portion 55 is one example of a “first insulating portion”. The insulating portion 55 is provided on the surface 31s of the insulating base material 31. The insulating portion 55 is provided in an interior of the opening 51h of the solder resist layer 51. For example, the insulating portion 55 is provided only in the interior of the opening 51h of the solder resist layer 51. The insulating portion 55 is provided between the first pad 42A and the second pad 42B in the X direction. An X direction width W55x of the insulating portion 55 is, for example, 0.1 mm or less.

FIG. 3 is a sectional view along an F3-F3 line of the substrate 21 shown in FIG. 2. The insulating portion 55 extends in the Y direction between the first pad 42A and the second pad 42B. For example, the insulating portion 55 extends linearly in the Y direction between the first pad 42A and the second pad 42B. In the present embodiment, a Y direction width W55y of the insulating portion 55 is large in comparison with a Y direction width W42y of the pad 42. The Y direction width W55y of the insulating portion 55 is large in comparison with a Y direction width W25y of the electronic part 25, to be described hereafter.

In the present embodiment, an edge 51he of the opening 51h of the solder resist layer 51 has a first edge 51he1, and a second edge 51he2 positioned on a side opposite to that of the first edge 51he1, as a pair of Y direction edges. In the present embodiment, the insulating portion 55 extends to reach the first edge 51he1 and the second edge 51he2 of the opening 51h of the solder resist layer 51.

In the present embodiment, the insulating portion 55 has a first end 56e1, and a second end 56e2 positioned on a side opposite to that of the first end 56e1, as a pair of Y direction ends. In the present embodiment, each of the first end 56e1 and the second end 56e2 of the insulating portion 55 is in contact with the solder resist layer 51. For example, the first end 56e1 is in contact with the first edge 51he1 of the opening 51h of the solder resist layer 51. The first end 56e1 is one example of a “third end”. In the same way, the second end 56e2 is in contact with the second edge 51he2 of the opening 51h of the solder resist layer 51.

Next, returning to FIG. 2, a Z direction thickness T55 of the insulating portion 55 will be described. The insulating portion 55 has the thickness (for example, a maximum thickness) T55 as a Z direction thickness. The insulating portion 55 has an end 55e positioned on a side opposite to that of the insulating base material 31 when seen in a cross-section following the Z direction (a cross-section shown in FIG. 2). The Z direction thickness T55 of the insulating portion 55 corresponds to a height of the end 55e of the insulating portion 55 with respect to the surface 31s of the insulating base material 31. The end 55e corresponds to one example of a “second end”.

In the present embodiment, the Z direction thickness (for example, the maximum thickness) T55 of the insulating portion 55 is large in comparison with the Z direction thickness (for example, the maximum thickness) T42 of the pad 42. In other words, the height of the end 55e of the insulating portion 55 with respect to the surface 31s of the insulating base material 31 is large in comparison with the height of the end 42e of the pad 42 with respect to the surface 31s of the insulating base material 31.

Meanwhile, the Z direction thickness (for example, the maximum thickness) T55 of the insulating portion 55 is small in comparison with the Z direction thickness (for example, the maximum thickness) T51 of the solder resist layer 51. In other words, the height of the end 55e of the insulating portion 55 with respect to the surface 31s of the insulating base material 31 is small in comparison with the height of the end 51e of the solder resist layer 51 with respect to the surface 31s of the insulating base material 31.

The insulating portion 55 includes a second insulating material. The second insulating material is an insulating material differing from the first insulating material. In the present application, “an insulating material differing from the first insulating material” means that it is sufficient that at least one of a component, a composition, a film property, an existence or otherwise, or a degree, of air bubbles in an interior, another property (for example, a viscosity before curing), or the like, differs in comparison with the first insulating material.

The second insulating material is, for example, an insulating material that can be applied using an inkjet method. For example, the second insulating material is an insulating material that has a low viscosity (for example, a viscosity at room temperature) before curing in comparison with that of the first insulating material. For example, the second insulating material is a resin-based insulating material adjusted in such a way that the viscosity at room temperature is low in comparison with that of the first insulating material. The insulating portion 55 is formed by, for example, applying the second insulating material onto the insulating base material 31 using an inkjet method, and curing the applied second insulating material by exposing to ultraviolet light, or the like. The second insulating material is, for example, an insulating material that is cured by exposure to ultraviolet light using a mercury lamp or a light emitting diode (LED). A method of curing the second insulating material, not being limited to the aforementioned method, may also be heating or the like.

### 2.3 Electronic Part

Next, the electronic part 25 will be described.

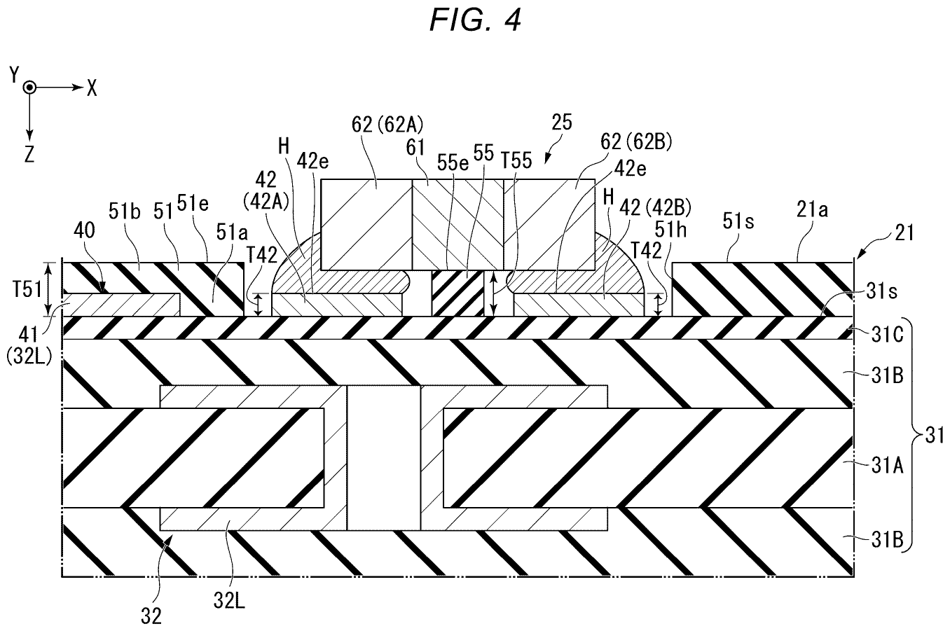

FIG. 4 is a sectional view showing one portion of the substrate unit 20. The electronic part 25 shown as an example in FIG. 4 is a chip capacitor, but this is not limiting. The electronic part 25 may also be a resistor, a diode, or another kind of part. The electronic part 25 has, for example, a part main body 61 and a multiple of terminals 62.

The part main body 61 is a portion that performs a main function of the electronic part 25. For example, the part main body 61 of the electronic part 25 that is a chip capacitor is a portion in which an electric charge is accumulated owing to a direct current voltage being applied.

The multiple of terminals 62 include a first terminal 62A and a second terminal 62B. The first terminal 62A and the second terminal 62B are disposed separated one on either side in the X direction of the part main body 61. The first terminal 62A is a terminal that is one of a positive electrode or a negative electrode. The first terminal 62A coincides with the first pad 42A when seen from the Z direction. The first terminal 62A is connected to the first pad 42A across a joining material H such as a solder. The second terminal 62B is a terminal that is the other of the positive electrode or the negative electrode. The second terminal 62B coincides with the second pad 42B when seen from the Z direction. The second terminal 62B is connected to the second pad 42B across the joining material H, which is a solder or the like.

The part main body 61 has an end 61e, which is an end on the insulating base material 31 side. The end 61e of the part main body 61 faces the insulating portion 55 in the Z direction. The end 61e of the part main body 61 is positioned near the insulating base material 31 in comparison with the end 51e of the solder resist layer 51. The end 61e of the part main body 61 may be in contact with the end 55e of the insulating portion 55.

Next, referring to FIG. 3, one example of a size of the electronic part 25 will be described. The electronic part 25 is a part of a rectangular form when seen from the Z direction. A width of a long side of the electronic part 25 (an X direction width W25x) is, for example, 0.4 mm or less. A width of a short side of the electronic part 25 (a Y direction width W25y) is, for example, 0.2 mm or less.

### 3. Substrate Unit Manufacturing Method

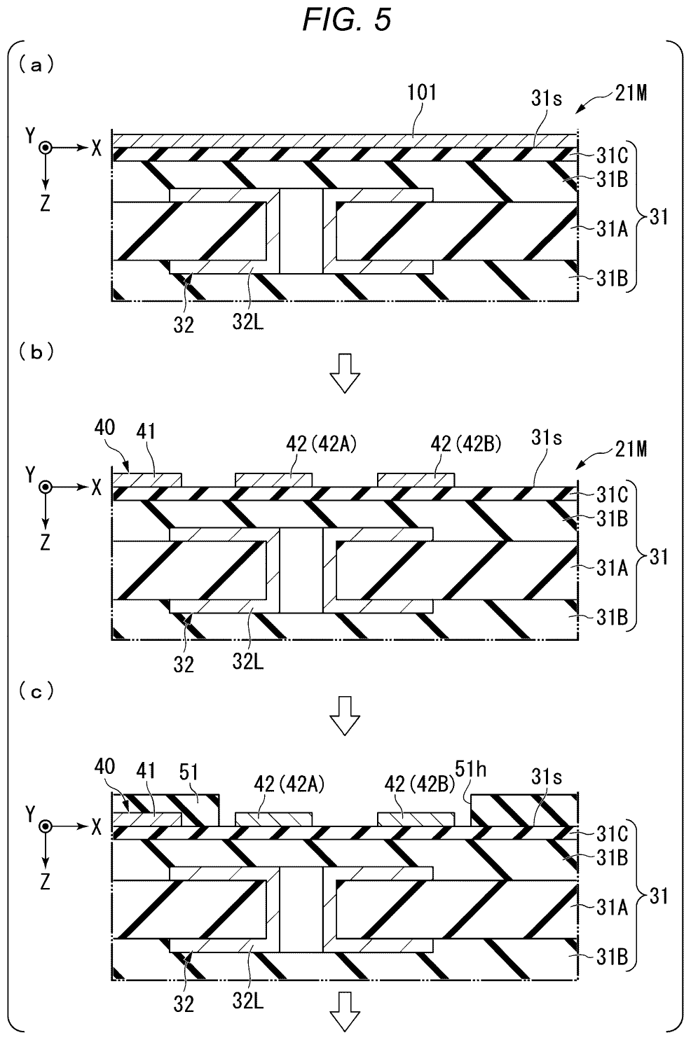

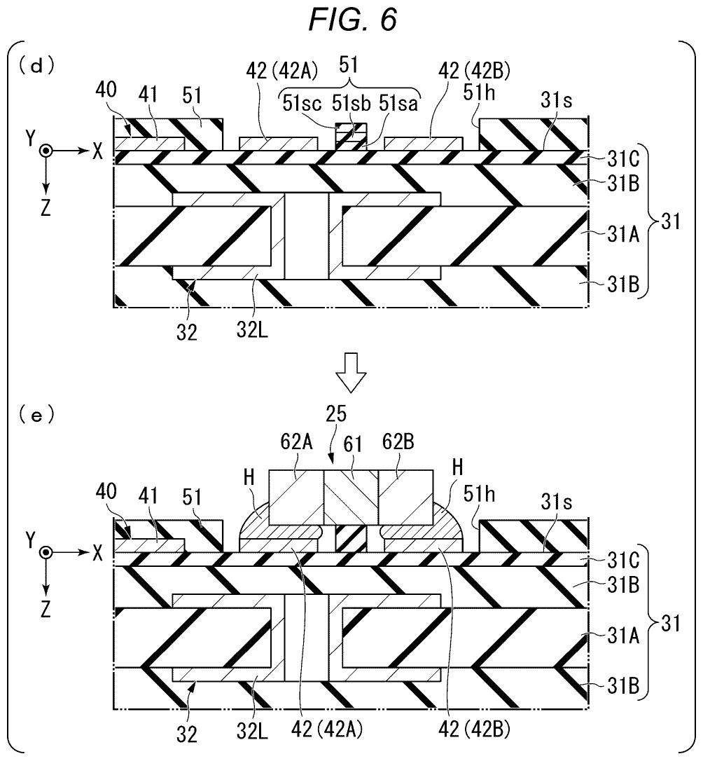

Next, a method of manufacturing the substrate unit 20 will be described. FIGS. 5 and 6 are sectional views showing a method of manufacturing the substrate unit 20. Firstly, an intermediate body 21M in which a conductive layer 101 is attached onto the surface 31s of the insulating base material 31 is prepared (refer to (a) in FIG. 5). Next, an unnecessary portion of the conductive layer 101 is removed by etching, whereby the conductive pattern 40 (for example, the wiring 41 and the pad 42) is formed from the conductive layer 101 (refer to (b) in FIG. 5).

Next, the solder resist layer 51 is provided on the surface 31s of the insulating base material 31 (refer to (c) in FIG. 5). For example, an insulating layer is formed first by the first insulating material being supplied to the surface 31s of the insulating base material 31 and a surface of the conductive pattern 40 and cured. Further, an unnecessary portion (for example, a portion corresponding to the opening 51h) of the insulating layer is removed by etching or the like. By so doing, the solder resist layer 51 is formed from the insulating layer.

Next, the insulating portion 55 is provided on the insulating base material 31 (refer to (d) in FIG. 6). For example, the insulating portion 55 is formed by the second insulating material being supplied using an inkjet method in a position between the first pad 42A and the second pad 42B inside the opening 51h of the solder resist layer 51, and cured. By so doing, the substrate 21 is completed.

In the present embodiment, an insulating material whose viscosity is low in comparison with that of the first insulating material is used as the second insulating material, in order to form the fine insulating portion 55. Because of this, it may be difficult to form the insulating portion 55 having a sufficient height with one application of the second insulating material using an inkjet method. In this case, the insulating portion 55 may be formed by application of the second insulating material using an inkjet method being repeated multiple times, or by application of the second insulating material using an inkjet method and curing being alternately repeated multiple times, whereby a multiple of insulating layers 51sa, 51sb, and 51sc are stacked in the Z direction.

Next, the electronic part 25 is mounted on the substrate 21 (refer to (e) in FIG. 6). In the present embodiment, the first terminal 62A of the electronic part 25 is placed on the first pad 42A across the joining material H, and the second terminal 62B of the electronic part 25 is placed on the second pad 42B across the joining material H. Further, by a reflow process being carried out, the first terminal 62A of the electronic part 25 is connected (joined) to the first pad 42A across the joining material H, and the second terminal 62B of the electronic part 25 is connected (joined) to the second pad 42B across the joining material H. By so doing, the electronic part 25 is mounted on the substrate 21. In this way, the substrate unit 20 is completed.

### 4. Advantages

As a first comparative example, a configuration such that no insulating portion exists between the first pad 42A and the second pad 42B will be considered. The configuration of the first comparative example may occur when, for example, the electronic part 25 is small, forming the solder resist layer 51 between the first pad 42A and the second pad 42B is difficult, and the opening 51h, which causes the first pad 42A and the second pad 42B to be exposed collectively, is provided.

The configuration of the first comparative example is such that when the first terminal 62A of the electronic part 25 is connected to the first pad 42A across the joining material H and the second terminal 62B of the electronic part 25 is connected to the second pad 42B across the joining material H (for example, when carrying out a reflow process), there is a case in which the joining material H for connecting the first terminal 62A to the first pad 42A and the joining material H for connecting the second terminal 62B to the second pad 42B melt in such a way as to approach each other and join together, and the first pad 42A and the second pad 42B short-circuit. When a manufacturing failure caused by this kind of short circuit occurs, a manufacturing yield of the substrate unit 20 decreases.

In the present embodiment, therefore, the substrate unit 20 has the insulating base material 31, the first pad 42A, the second pad 42B, the solder resist layer 51, the insulating portion 55, and the electronic part 25. The solder resist layer 51 has the opening 51h, which causes the first pad 42A and the second pad 42B to be exposed. The insulating portion 55 is provided between the first pad 42A and the second pad 42B in the opening 51h. The electronic part 25 has the first terminal 62A, which is connected to the first pad 42A across the joining material H, and the second terminal 62B, which is connected to the second pad 42B across the joining material H. The solder resist layer 51 includes the first insulating material. The insulating portion 55 includes the second insulating material differing from the first insulating material. The Z direction thickness (for example, the maximum thickness) T55 of the insulating portion 55 is large in comparison with the Z direction thickness (for example, the maximum thickness) T42 of the first pad 42A.

This kind of configuration is such that even when forming the solder resist layer 51 between the first pad 42A and the second pad 42B is difficult, the insulating portion 55 can be provided between the first pad 42A and the second pad 42B using another method. When the insulating portion 55 can be provided between the first pad 42A and the second pad 42B, a joining together of the joining material H for connecting the first terminal 62A to the first pad 42A and the joining material H for connecting the second terminal 62B to the second pad 42B can be restricted. Because of this, a restriction of an occurrence of manufacturing failures of the substrate unit 20 can be achieved.

In the present embodiment, the Z direction thickness (for example, the maximum thickness) T55 of the insulating portion 55 is small in comparison with the Z direction thickness (for example, the maximum thickness) T51 of the first portion 51a of the solder resist layer 51. According to this kind of configuration, an amount by which the insulating portion 55 protrudes from the surface 31s of the insulating base material 31 is limited, and even when, for example, the small electronic part 25 is mounted, the insulating portion 55 being an impediment and the electronic part 25 being difficult to be mounted (for example, a mounting height of the electronic part 25 being high) can be restricted. Because of this, an improvement in manufacturability of the substrate unit 20, and/or a reduction in thickness of the substrate unit 20, can be achieved.

In the present embodiment, the insulating portion 55 is formed by an insulating material being applied using an inkjet method, and cured. According to this kind of configuration, the fine insulating portion 55 is easy to form in comparison with a method of forming the solder resist layer 51. Because of this, the insulating portion 55 is easily provided between the first pad 42A and the second pad 42B, even when forming the solder resist layer 51 between the first pad 42A and the second pad 42B is difficult.

Also, when forming the insulating portion 55 using an inkjet method, a thickness differing from the Z direction thickness T51 of the solder resist layer 51 is easily obtained as the thickness T55 of the insulating portion 55. This means that when forming the insulating portion 55 using an inkjet method, the Z direction thickness T55 of the insulating portion 55 is easily formed to be smaller than the Z direction thickness T51 of the solder resist layer 51.

In the present embodiment, at least one of the Y direction first end 56e1 and second end 56e2 of the insulating portion 55 is in contact with the solder resist layer 51. According to this kind of configuration, a joining together of the joining material H for connecting the first terminal 62A to the first pad 42A and the joining material H for connecting the second terminal 62B to the second pad 42B can be more reliably restricted.

### Second Embodiment

Next, a second embodiment will be described. The second embodiment differs from the f first embodiment in that the insulating portion 55 is separated from the edge 51he of the opening 51h of the solder resist layer 51. Configurations other than that described hereafter are the same as the configurations of the first embodiment.

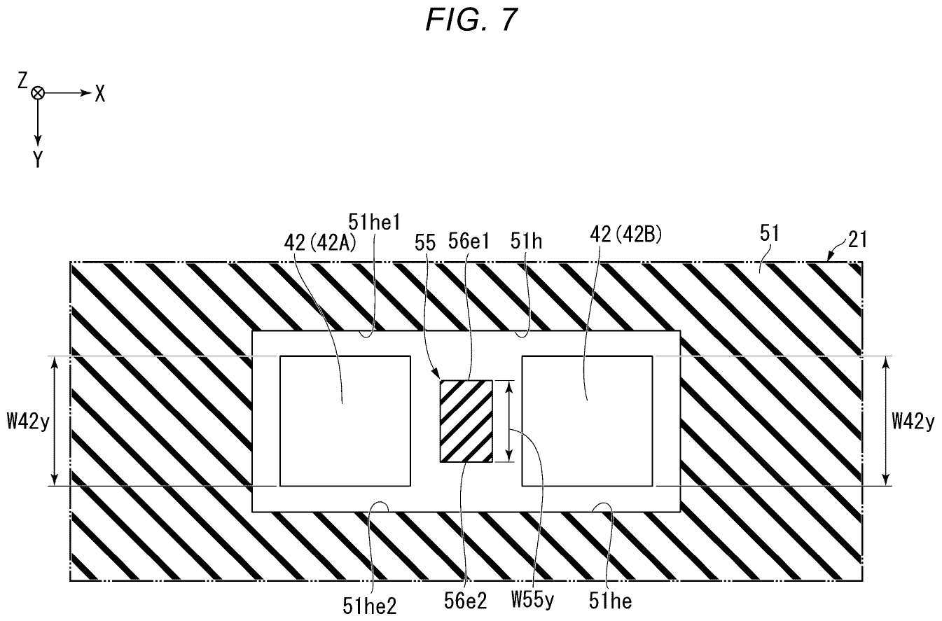

FIG. 7 is a sectional view showing one portion of the substrate 21 of the second embodiment. In the present embodiment, the insulating portion 55 is positioned between the first pad 42A and the second pad 42B, and extends in the Y direction. In the present embodiment, the Y direction width W55y of the insulating portion 55 is small in comparison with the Y direction width W42y of the pad 42. For example, the Y direction width W55y of the insulating portion 55 is one half or greater of the Y direction width W42y of the pad 42, but is small in comparison with the Y direction width W42y of the pad 42.

In the present embodiment, the insulating portion 55 has the first end 56e1, and the second end 56e2 positioned on a side opposite to that of the first end 56e1, as a pair of Y direction ends. In the present embodiment, each of the first end 56e1 and the second end 56e2 of the insulating portion 55 is separated from the solder resist layer 51. For example, the first end 56e1 is separated from the first edge 51he1 of the opening 51h of the solder resist layer 51. In the same way, the second end 56e2 is separated from the second edge 51he2 of the opening 51h of the solder resist layer 51.

This kind of configuration is also such that, owing to the insulating portion 55 being provided, a joining together of the joining material H for connecting the first terminal 62A to the first pad 42A and the joining material H for connecting the second terminal 62B to the second pad 42B can easily be restricted because of the insulating portion 55. Because of this, a restriction of an occurrence of manufacturing failures of the substrate unit 20 can be achieved.

In the present embodiment, at least one of the Y direction first end 56e1 and second end 56e2 of the insulating portion 55 is separated from the edge 51he of the opening 51h of the solder resist layer 51. According to this kind of configuration, it may be easier to form the insulating portion 55 in the interior of the opening 51h of the solder resist layer 51. Because of this, an improvement in manufacturability of the substrate unit 20 can be achieved.

### Third Embodiment

Next, a third embodiment will be described. The third embodiment differs from the first embodiment in that an insulating portion 131 is provided instead of/in addition to the insulating portion 55. Configurations other than that described hereafter are the same as the configurations of the first embodiment.

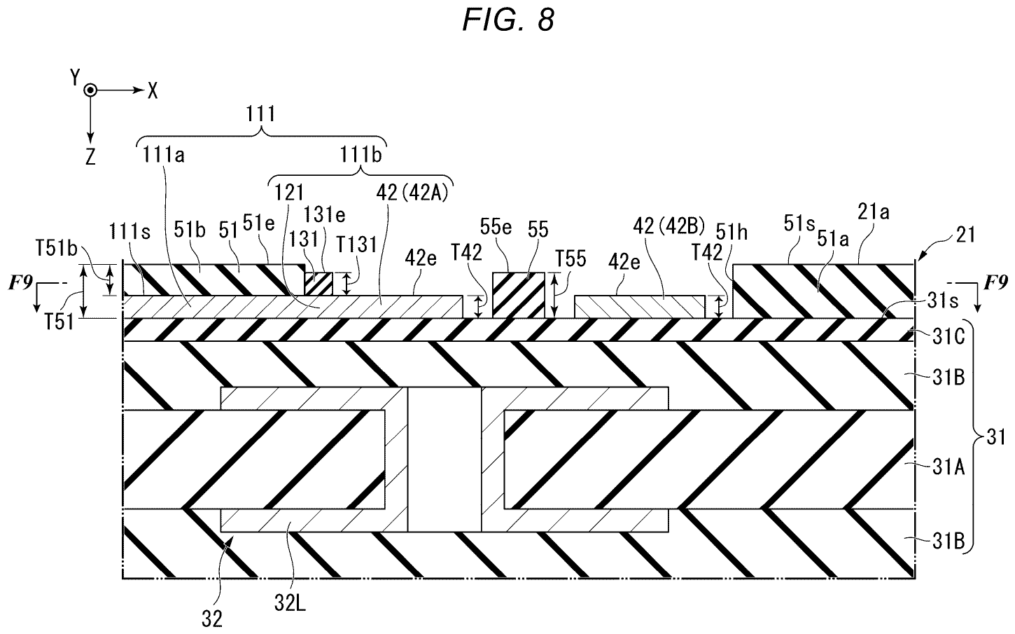

FIG. 8 is a sectional view showing one portion of the substrate 21 of the third embodiment. In the present embodiment, the conductive pattern 40 in the surface layer portion of the substrate 21 includes a conductive layer 111 and the second pad 42B.

### Conductive Layer

The conductive layer 111 is a conductive portion that extends in plate form in the X direction and the Y direction. The conductive layer 111 is provided on the surface 31s of the insulating base material 31. The conductive layer 111 is, for example, a power supply layer or a ground layer. The conductive layer 111 includes a first region 111a and a second region 111b. The first region 111a is a region covered by the second portion 51b of the solder resist layer 51. Meanwhile, the second region 111b is a region that is not covered by the solder resist layer 51. The second region 111b is a region disposed in the interior of the opening 51h of the solder resist layer 51 when seen from the Z direction. The conductive layer 111 has a surface 111s positioned on a side opposite to that of the insulating base material 31. The surface 111s extends in the X direction and the Y direction.

The second region 111b includes the first pad 42A and a non-pad portion 121. The non-pad portion 121 is a portion that is disposed between the first pad 42A and the first region 111a, and joins the first pad 42A and the first region 111a.

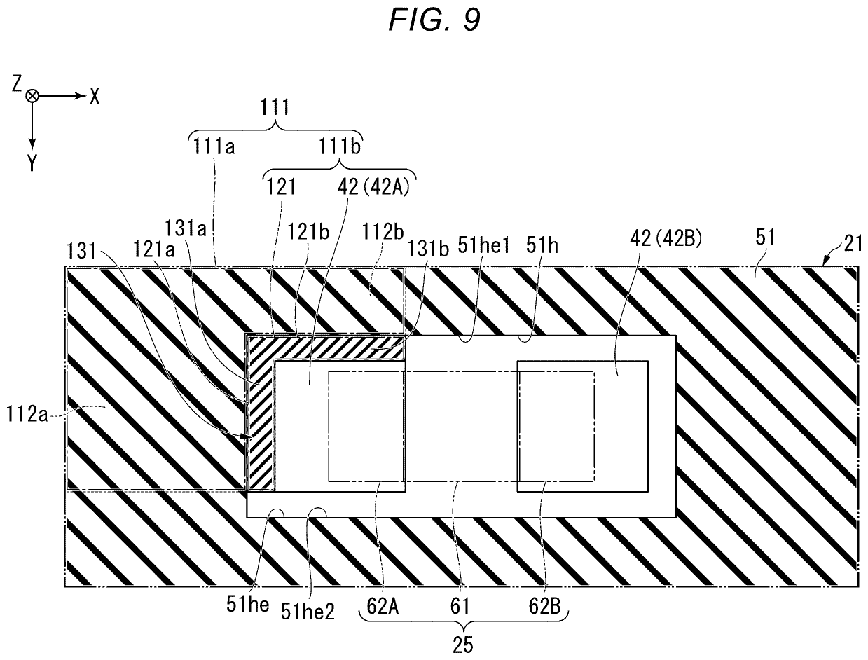

FIG. 9 is a sectional view along an F9-F9 line of the substrate 21 shown in FIG. 8. In the present embodiment, the first region 111a of the conductive layer 111 includes a first portion 112a and a second portion 112b. The first portion 112a is a portion that is aligned with the first pad 42A in the X direction. The first portion 112a is positioned on a side opposite to that of the second pad 42B with respect to the first pad 42A in the X direction. Meanwhile, the second portion 112b is a portion that is aligned with the first pad 42A in the Y direction. In the present embodiment, the first portion 112a and the second portion 112b are formed integrated. The first region 111a need have only one of the first portion 112a and the second portion 112b.

As heretofore described, the second region 111b of the conductive layer 111 includes the first pad 42A and the non-pad portion 121. The first pad 42A is a region symmetrical with the second pad 42B in the second region 111b of the conductive layer 111. The non-pad portion 121 is a region disposed between the first pad 42A and the first region 111a.

In the present embodiment, the non-pad portion 121 has the first portion 121a and the second portion 121b. The first portion 121a is a region disposed between the first portion 112a of the first region 111a of the conductive layer 111 and the first pad 42A in the X direction. The first portion 121a extends in the Y direction. Meanwhile, the second portion 121b is a region disposed between the second portion 112b of the first region 111a of the conductive layer 111 and the first pad 42A in the Y direction. The second portion 121b extends in the X direction. In the present embodiment, the first portion 121a and the second portion 121b are formed integrated. Because of this, the L-shaped non-pad portion 121 is formed.

### Insulating Portion

Next, the insulating portion 131 will be described. The insulating portion 131 is one example of a “second insulating portion”. The insulating portion 131 is an insulating portion provided on the surface 111s of the conductive layer 111. The insulating portion 131 is provided on the non-pad portion 121. When seen from the Z direction, the insulating portion 131 is provided between one portion of the edge 51he of the opening 51h of the solder resist layer 51 and the electronic part 25.

In the present embodiment, the insulating portion 131 has a first portion 131a and a second portion 131b. The first portion 131a is provided on the first portion 121a of the non-pad portion 121. The first portion 131a is provided between the edge 51he of the opening 51h of the solder resist layer 51 and the electronic part 25 in the X direction. The first portion 131a extends in the Y direction. Meanwhile, the second portion 131b is provided on the second portion 121b of the non-pad portion 121. The second portion 131b is provided between the edge 51he (for example, the first edge 51he1) of the opening 51h of the solder resist layer 51 and the electronic part 25 in the Y direction. The second portion 131b extends in the X direction. In the present embodiment, the first portion 131a and the second portion 131b are formed integrated. Because of this, the L-shaped insulating portion 131 is formed. Owing to the insulating portion 131 being provided, only a region of the non-pad portion 121 corresponding to the first pad 42A is exposed to an exterior of the substrate 21, and can be joined to the joining material H.

Next, returning to FIG. 8, a thickness T131 of the insulating portion 131 will be described. The insulating portion 131 has the thickness (for example, a maximum thickness) T131 as a Z direction thickness. The insulating portion 131 has an end 131e positioned on a side opposite to that of the insulating base material 31 when seen in a cross-section following the Z direction (a cross-section shown in FIG. 8). The Z direction thickness T131 of the insulating portion 131 corresponds to a height of the end 131e of the insulating portion 131 with respect to the surface 111s of the conductive layer 111. In the present embodiment, the Z direction thickness (for example, the maximum thickness) T131 of the insulating portion 131 is small in comparison with the Z direction thickness (for example, the maximum thickness) T51 of the solder resist layer 51. More specifically, the Z direction thickness (for example, the maximum thickness) T131 of the insulating portion 131 is small in comparison with a Z direction thickness (for example, a maximum thickness) T51b of the second portion 51b of the solder resist layer 51.

The insulating portion 131 includes the aforementioned second insulating material. In the same way as the insulating portion 55, the insulating portion 131 is formed by, for example, applying the second insulating material onto the insulating base material 31 using an inkjet method, and curing the applied second insulating material by exposing to ultraviolet light, or the like. A method of curing the second insulating material, not being limited to the aforementioned method, may also be heating or the like.

As a second comparative example, a configuration such that the insulating portion 131 does not exist will be considered. The second comparative example is such that when seen from the Z direction, a form of the second region 111b of the conductive layer 111 and a form of the second pad 42B differ. Because of this, a positional deviation of the electronic part 25 from an appropriate position (for example, a positional deviation accompanying a rotation) may occur when a reflow process is carried out.

Meanwhile, in the present embodiment, the substrate 21 is provided between one portion of the edge 51he of the opening 51h of the solder resist layer 51 and the electronic part 25, and includes the insulating portion 131 including the second insulating material. According to this kind of configuration, for example, a range of positional deviation of the electronic part 25 is regulated by the insulating portion 131. Because of this, a restriction of an occurrence of manufacturing failures of the substrate unit 20 can be achieved.

In the present embodiment, the conductive layer 111 includes the first region 111a, which is covered by the solder resist layer 51, and the second region 111b, which is disposed in the opening 51h of the solder resist layer 51 and includes the first pad 42A. The insulating portion 131 is provided on the conductive layer 111 inside the opening 51h of the solder resist layer 51. According to this kind of configuration, a region in which the joining material H is joined in the second region 111b of the conductive layer 111 can be limited by the insulating portion 131 being provided. Because of this, the forms of the first pad 42A and the second pad 42B can be brought close together, and positional deviation of the electronic part 25 can be further restricted. Because of this, a further restriction of an occurrence of manufacturing failures of the substrate unit 20 can be achieved.

In the present embodiment, the Z direction thickness (for example, the maximum thickness) T131 of the insulating portion 131 is small in comparison with the Z direction thickness (for example, the maximum thickness) T51b of the second portion 51b of the solder resist layer 51. According to this kind of configuration, the insulating portion 131 does not protrude from the surface 51s of the solder resist layer 51. Because of this, an improvement in manufacturability of the substrate unit 20, and/or a reduction in thickness of the substrate unit 20, can be achieved.

### Fourth Embodiment

Next, a fourth embodiment will be described. The fourth embodiment differs from the first embodiment in that an insulating portion 55 is provided to accommodate the ball grid array (BGA) pad 42. Configurations other than that described hereafter are the same as the configurations of the first embodiment.

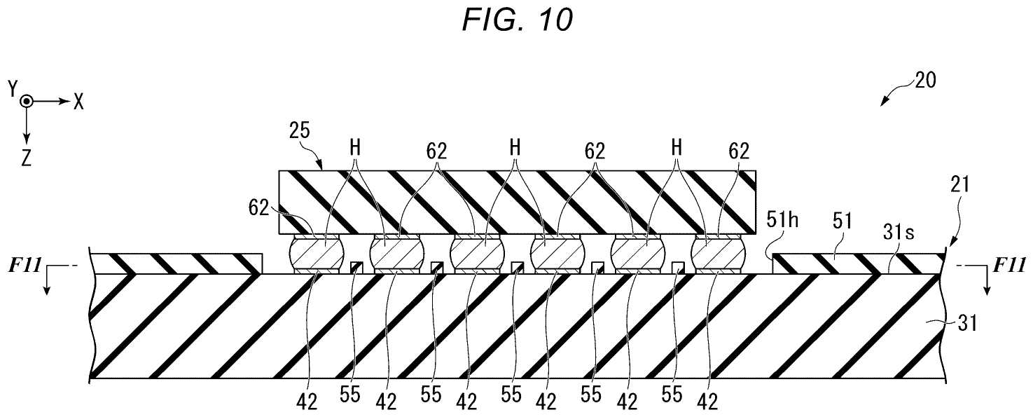

FIG. 10 is a sectional view showing one portion of the substrate unit 20 of the fourth embodiment. In the present embodiment, the electronic part 25 is a BGA type semiconductor package. The electronic part 25 has a multiple of terminals 62. The multiple of terminals 62 are disposed in lattice form in the X direction and the Y direction. The joining material H, which is a solder ball, is joined to each terminal 62.

In the present embodiment, the substrate 21 has a multiple of the pad 42 that accommodate a BGA type solder package. The multiple of pads 42 are provided on the surface 31s of the insulating base material 31. The multiple of pads 62 are disposed in lattice form in the X direction and the Y direction. The terminal 62 of the electronic part 25 is connected to each pad 42 via the joining material H.

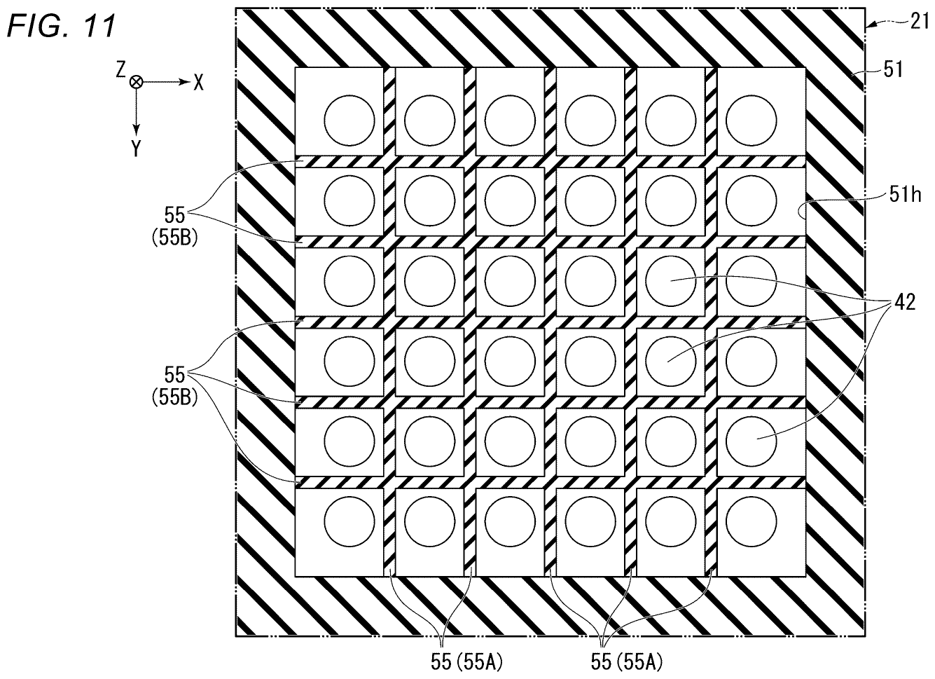

FIG. 11 is a sectional view along an F11-F11 line of the substrate 21 shown in FIG. 10. In the present embodiment, the insulating portion 55 is provided among the multiple of pads 42. The insulating portion 55 includes, for example, a multiple of insulating portions 55A and a multiple of insulating portions 55B. Each of the multiple of insulating portions 55A is disposed between two pads 42 neighboring in the X direction. Each of the multiple of insulating portions 55A extends in the Y direction among a multiple of pads 42 arrayed in two lines. Meanwhile, each of the multiple of insulating portions 55B is disposed between two pads 42 neighboring in the Y direction. Each of the multiple of insulating portions 55B extends in the X direction among a multiple of pads 42 arrayed in two lines.

According to this kind of configuration, the joining material H joining together among the multiple of pads 42, and a short circuit occurring, can be restricted. Because of this, a restriction of an occurrence of manufacturing failures of the substrate unit 20 can be achieved.

Heretofore, a number of embodiments have been described. However, embodiments are not limited to the heretofore described examples. For example, the heretofore described multiple of embodiments may be realized by being combined with each other.

According to at least one of the heretofore described embodiments, a substrate unit has an insulating base material, a first pad, a second pad, a solder resist layer, a first insulating portion, and an electronic part. The solder resist layer has an opening that causes the first pad and the second pad to be exposed. The first insulating portion is provided between the first pad and the second pad in the opening. The solder resist layer includes a first insulating material. The first insulating portion includes a second insulating material differing from the first insulating material. When a direction heading from the first pad toward the insulating base material is a first direction, a thickness in the first direction of the first insulating portion is large in comparison with a thickness in the first direction of the first pad. According to this kind of configuration, a restriction of an occurrence of manufacturing failures of the substrate unit can be achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate unit, comprising:
an insulating substrate;
a first pad provided on the insulating substrate;
a second pad provided on the insulating substrate;
a solder resist layer including a portion provided on the insulating substrate and an opening exposing the first pad and the second pad;
a first insulating portion provided between the first pad and the second pad in the opening; and
an electronic part having a first terminal connected to the first pad across a joining material and a second terminal connected to the second pad across a joining material, wherein
the solder resist layer includes a first insulating material,
the first insulating portion includes a second insulating material different from the first insulating material, and
a length in a first direction of the first insulating portion is greater than a length in the first direction of the first pad, the first direction being a direction extending from the first pad toward the insulating substrate.

2. The substrate unit according to claim 1, wherein
the insulating substrate has a first face,
the first pad and the first insulating portion are provided on the first face,
the first pad has a first end positioned on a side opposite to the first face,
the first insulating portion has a second end positioned on a side opposite to the first face, and
a height of the second end of the first insulating portion from the first face is greater than a height of the first end of the first pad from the first face.

3. The substrate unit according to claim 1, further comprising a wiring provided on the insulating substrate, wherein
the solder resist layer includes a first portion in contact with the insulating substrate and a second portion covering the wiring, and
a length in the first direction of the first insulating portion is less than a length in the first direction of the first portion of the solder resist layer.

4. The substrate unit according to claim 1, wherein
the first insulating portion is formed by applying the second insulating material with an inkjet method, and curing the applied second insulating material.

5. The substrate unit according to claim 1, wherein,
the first insulating portion has a third end in a third direction of the first insulating portion, the third direction being a direction extending from the first pad toward the second pad is a second direction and a direction intersecting the first direction and the second direction, and
the third end is in contact with the solder resist layer.

6. The substrate unit according to claim 1, wherein,
the first insulating portion has a third end in a third direction of the first insulating portion, the third direction being a direction extending from the first pad toward the second pad is a second direction and a direction intersecting the first direction and the second direction, and
the third end is separated from an edge of the opening.

7. The substrate unit according to claim 1, further comprising a second insulating portion provided between one portion of an edge of the opening and the electronic part when viewed from the first direction, the second insulating portion including the second insulating material.

8. The substrate unit according to claim 7, further comprising a conductive layer having a first region and a second region, the first region being covered by the solder resist layer and a second region disposed in the opening, the second region including the first pad, wherein
the second insulating portion is provided on the conductive layer in the opening.

9. The substrate unit according to claim 8, wherein
the solder resist layer includes a first portion in contact with the insulating substrate and a second portion covering the first region of the conductive layer, and
a length in the first direction of the second insulating portion is less than a length in the first direction of the second portion of the solder resist layer.

10. The substrate unit according to claim 1, wherein
the electronic part is a part of a rectangular form when viewed from the first direction,
a width of a first side of the electronic part is equal to or less than 0.4 mm, and
a width of a second side of the electronic part is equal to or less than 0.2 mm.

11. A substrate unit, comprising:
an insulating substrate;
a first pad provided on the insulating substrate;
a second pad provided on the insulating substrate;
a wiring provided on the insulating substrate;
a solder resist layer including a first portion in contact with the insulating substrate and a second portion covering the wiring, and an opening exposing the first pad and the second pad;
a first insulating portion provided between the first pad and the second pad in the opening; and
an electronic part having a first terminal connected to the first pad across a joining material and a second terminal connected to the second pad across a joining material, wherein,
a length in a first direction of the first insulating portion is less than a length in the first direction of the first portion of the solder resist layer, the first direction being a direction extending from the first pad toward the insulating substrate.

12. The substrate unit according to claim 11, wherein
the insulating substrate has a first face,
the first pad and the first insulating portion are provided on the first face,
the first pad has a first end positioned on a side opposite to the first face,
the first insulating portion has a second end positioned on a side opposite to the first face, and
a height of the second end of the first insulating portion from the first face is greater than a height of the first end of the first pad from the first face.

13. The substrate unit according to claim 11, wherein,
the first insulating portion has a third end in a third direction of the first insulating portion, the third direction being a direction extending from the first pad toward the second pad is a second direction and a direction intersecting the first direction and the second direction, and
the third end is in contact with the solder resist layer.

14. The substrate unit according to claim 11, wherein,
the first insulating portion has a third end in the third direction of the first insulating portion, the third direction being a direction extending from the first pad toward the second pad is a second direction and a direction intersecting the first direction and the second direction, and
the third end is separated from an edge of the opening.

15. The substrate unit according to claim 11, wherein
the solder resist layer includes a first insulating material,
the first insulating portion includes a second insulating material different from the first insulating material,
the first insulating portion is formed by applying the second insulating material with an inkjet method and curing the applied second insulating material.

16. The substrate unit according to claim 15, further comprising:
a second insulating portion provided between one portion of an edge of the opening and the electronic part when viewed from the first direction, the second insulating portion including the second insulating material, and
a conductive layer having a first region and a second region, the first region being covered by the solder resist layer, the second region being disposed in the opening and including the first pad, wherein
the second insulating portion is provided on the conductive layer in the opening.

17. The substrate unit according to claim 11, wherein
the electronic part is a part of a rectangular form when viewed from the first direction,
a width of a first side of the electronic part is equal to or less than 0.4 mm, and
a width of a second side of the electronic part is equal to or less than 0.2 mm.

18. A substrate unit, comprising:
an insulating substrate;
a first pad provided on the insulating substrate;
a second pad provided on the insulating substrate;
a solder resist layer including a portion provided on the insulating substrate and an opening exposing the first pad and the second pad;
an electronic part having a first terminal connected to the first pad across a joining material and a second terminal connected to the second pad across a joining material; and
an insulating portion provided between one portion of an edge of the opening and the electronic part when viewed from a first direction extending from the first pad toward the insulating substrate, wherein
the solder resist layer includes a first insulating material,
the insulating portion includes a second insulating material different from the first insulating material, and
a length in the first direction of the insulating portion is less than a length in the first direction of the solder resist layer.

19. The substrate unit according to claim 18, wherein
the insulating substrate has a first face,
the first pad and the first insulating portion are provided on the first face,
the first pad has a first end positioned on a side opposite to the first face,
the first insulating portion has a second end positioned on a side opposite to the first face, and
a height of the second end of the first insulating portion from the first face is greater than a height of the first end of the first pad from the first face.

20. The substrate unit according to claim 18, wherein,
the first insulating portion has a third end in a third direction of the first insulating portion, the third direction being a direction extending from the first pad toward the second pad is a second direction and a direction intersecting the first direction and the second direction, and
the third end is in contact with the solder resist layer.
